(19) United States
(12) Patent Application Publication
(10) Pub. No.: US 2003/0109110 A1
(43) Pub. Date: Jun. 12, 2003

(54) Method for forming capacitor of a semiconductor device

(76) Inventor: Kyong Min Kim, Kyoungki-do (KR)

Correspondence Address: MARSHALL, GERSTEIN & BORUN, 6300 SEARS TOWER, 233 SOUTH WACKER, CHICAGO, IL, 60606-6357, US

(21) Appl. No.: 10/315,364

(22) Filed: Dec. 10, 2002

(30) Foreign Application Priority Data
Dec. 10, 2001 (KR) 2001-77849

(51) Int. Cl. H01L 21/20; H01L 21/8242; H01L 21/44

(52) U.S. Cl. 438/398; 438/686; 438/681

(57) ABSTRACT

A method for forming a capacitor of a semiconductor device which provides improved reliability and characteristics of semiconductor device by removing oxygen from the Ru film using NH₃ gas during the deposition process of the Ru film used as storage electrode material or, in the alternative, performing a NH₃ plasma treatment after the deposition process of Ru film to inhibit formation of oxide film at the interface of Ru film and barrier metal layer, and then by forming rugged surface on the Ru film with RTP under N₂ or NH₃ gas atmosphere to obtain a high capacitance for high integration of semiconductor device.

### BACKGROUND

1. Technical Field

Methods for forming capacitors of semiconductor devices are disclosed, and more particularly, methods for forming capacitors comprising a dielectric film formed of high dielectric constant material and a storage electrode formed of ruthenium (hereinafter, referred to as “Ru”) film are disclosed wherein oxygen in the Ru film is removed to prevent degradation of the electrical characteristics of the devices generated during the subsequent thermal treatment process and further to provide Ru films with rugged surfaces thereby increasing the surface area thereof and obtaining high capacitances of the capacitors.

2. Description of the Related Art

As the cell size is decreased due to high integration of semiconductor devices, it is difficult to obtain sufficient capacitance which is proportional to the surface area of storage electrode.

Specifically, in case of DRAM device having a unit cell consisting of a MOS transistor and a capacitor, the significant factor for high integration is to increase the capacitance of a capacitor which occupies much space of each unit cell.

The capacitance of a capacitor follows the equation of (Eo×Er×A)/T (Eo: permittivity of vacuum, Er: dielectric constant of dielectric film, A: surface area of capacitor, T: thickness of dielectric film), and one of the methods for increasing the capacitance is to increase the surface area of storage electrode.

Although not shown in the drawings, a method for forming a capacitor of a semiconductor device in accordance with the conventional art is described.

A planarized lower insulating layer is formed on a semiconductor substrate comprising a device isolation film, a word line and a bit line.

The lower insulating layer is formed of insulating materials having high fluidity such as BPSG (Boro Phospho Silicate Glass).

A storage electrode contact hole exposing a predetermined portion of the semiconductor substrate is formed in the lower insulating layer.

The storage electrode contact hole is formed by etching the lower insulating layer via a photo-etching process using a storage electrode contact mask.

Next, a contact plug is formed to fill the storage electrode contact hole.

The contact plug comprises a stacked structure of polysilicon film/Ti film/TiN film.

A Ru film, which is a metal layer for storage electrode, is then formed on the resultant structure.

The Ru film is deposited using a chemical vapor deposition (hereinafter, referred to as ‘CVD’) method and thermally treated under N₂ gas atmosphere at a temperature of 600° C. for 60 seconds.

A dielectric film comprising a tantalum oxide film is formed on the Ru film, and an upper electrode is then formed on the dielectric film using a Ru film or a TiN film.

However, during the subsequent thermal treatment, oxygen atoms contained in the Ru film, which is the storage electrode oxidize the TiN film in the contact plug and result in the formation of an oxide film.

That is, an oxide film is formed at the interface of the Ru film and the TiN film, which results in degradation of electrical characteristics of capacitors of semiconductor devices and lift-off of Ru films.

As described above, in the conventional method for forming a capacitor of a semiconductor device, the oxide film formed at the interface of TiN film and Ru film degrades the electrical characteristics of devices. In addition, an overhang occurs due to the height requirement of the capacitor in order to provide sufficient capacitance for high integration of semiconductor, which causes degradation of step coverage during the deposition process of Ru film, thereby degrading reliability and characteristics of devices and hinders high integration of semiconductor devices.

### SUMMARY OF THE DISCLOSURE

Accordingly, a method for forming a capacitor of a semiconductor device is disclosed wherein oxygen in the Ru film is removed to prevent degradation of characteristics of devices generated during the subsequent thermal treatment process and of Ru film having rugged surface to obtain a sufficiently high capacitance.

To achieve the high capacitance, a method for forming a storage electrode of a capacitor of a semiconductor device is disclosed which comprises:

(a) forming a Ru film by performing a CVD process at the presence of NH₃ gas; and

(b) thermally treating the Ru film under N₂ or NH₃ atmosphere to form a rugged surface on the Ru film.

First, one disclosed method is characterized in that:

the step (a) is performed at the presence of O₂ gas as a reaction gas;

the flow ratio of O₂ gas:NH₃ gas is 1:2˜20;

the step (a) is performed under the condition that wafer temperature ranges from 250 to 350° C., reaction chamber pressure ranges from 0.1 to 10 torr, Ru source material is Tris(2,4-octanedionato)ruthenium or Bis(ethylcyclopentadienyl)ruthenium, flow rate of O₂ reaction gas ranges from 10 to 1000 seem and flow rate of NH₃ gas ranges from 100 to 2000 seem; and the thickness of the Ru film obtained ranges from 100 to 500 Å;

the step (b) is performed by RTP (Rapid Thermal Processing);

the RTP is performed for 30 to 120 seconds under the condition that wafer temperature ranges from 500 to 700° C., and flow rate of N₂ or NH₃ gas ranges from 100 to 5000 sccm;

the step (a) further comprises the step of subjecting the Ru film to NH₃ plasma treatment; and

the NH₃ plasma treatment is performed for 5 to 300 seconds under the condition that reaction chamber pressure is ranging from 0.1 to 2.0 torr, NH₃ gas flow rate ranges from 30 to 1000 seem and RF electric power ranges from 30 to 400 Watt.

There is also provided a method for forming a storage electrode of a capacitor of a semiconductor device, comprising:

(a) forming a Ru film by performing a CVD process;

(b) subjecting the Ru film to a NH₃ plasma treatment; and

(c) thermally treating the Ru film under N₂ or NH₃ atmosphere to form a rugged surface on the Ru film.

Second, another disclosed method is characterized in that:

the step (a) is performed at the presence of O₂ gas as a reaction gas;

the step (a) is performed under the condition that wafer temperature ranges from 250 to 350° C., reaction chamber pressure ranges from 0.1 to 10 torr, Ru source material is Tris(2,4-octanedionato)ruthenium or Bis(ethylcyclopentadienyl)ruthenium, flow rate of O₂ reaction gas ranges from 10 to 1000 seem and flow rate of NH₃ gas ranges from 100 to 2000 sccm; and the thickness of the Ru film obtained ranges from 100 to 500 Å;

the step (b) is performed for 5 to 300 seconds under the condition that reaction chamber pressure is ranging from 0.1 to 2.0 torr, NH3 gas flow rate ranges from 30 to 1000 sccm and RF electric power ranges from 30 to 400 Watt;

the step (b) is performed by RTP (Rapid Thermal Processing); and

the RTP is performed for 30 to 120 seconds under the condition that wafer temperature ranges from 500 to 700° C., and flow rate of N₂ or NH₃ gas ranges from 100 to 5000 sccm.

The oxygen in the Ru film is removed by injecting NH₃ gas during the deposition process of the Ru film which is used as electrode for deoxidation. Further, formation of an oxide film at the interface of Ru film and barrier metal layer is prevented by performing NH₃ plasma treatment after the deposition of Ru film to remove oxygen in Ru film. As a result, a capacitance sufficient for highly integrated semiconductor devices is obtained by performing RTP on Ru film under N₂ or NH₃ gas atmosphere to form a rugged surface without increasing the height of capacitor.

### BRIEF DESCRIPTION OF THE DRAWINGS

FIGS. 1a to 1g are cross-sectional diagrams illustrating a method for forming a capacitor of a semiconductor device in accordance with a disclosed embodiment.

FIGS. 2a and 2b are TEM photographs respectively illustrating the Ru film before and after RTP treatment formed in accordance with another preferred embodiment.

### DETAILED DESCRIPTION OF THE PRESENTLY PREFERRED EMBODIMENTS

A method for forming a capacitor of a semiconductor device according to this disclosure will be described in greater detail referring to the accompanying drawings.

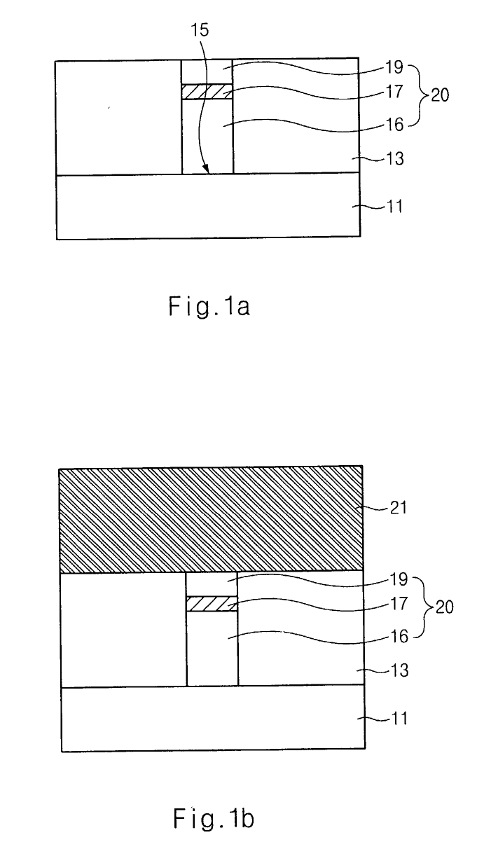

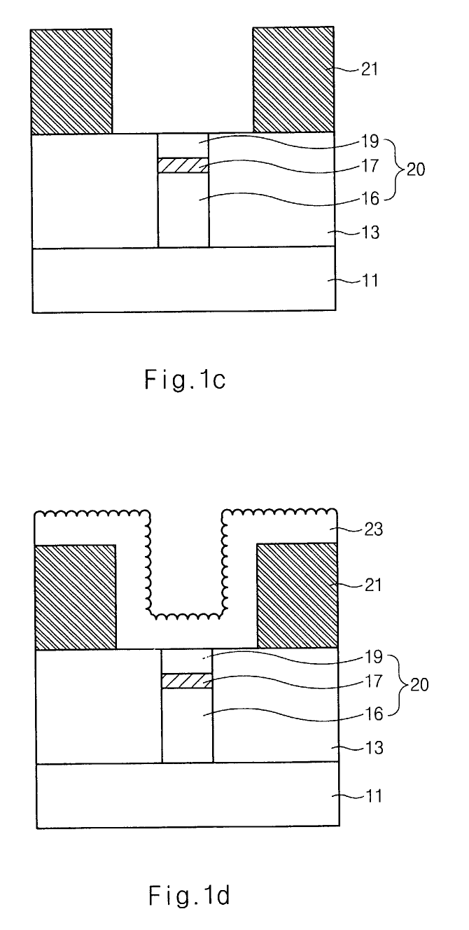

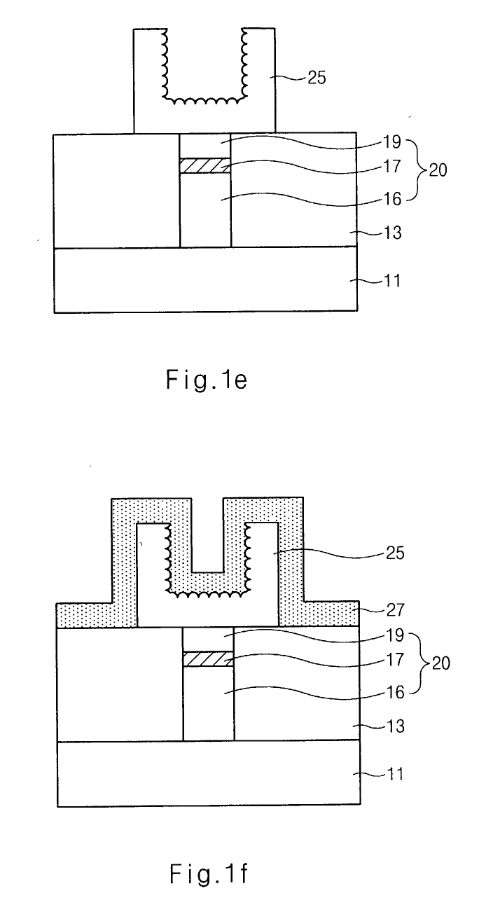

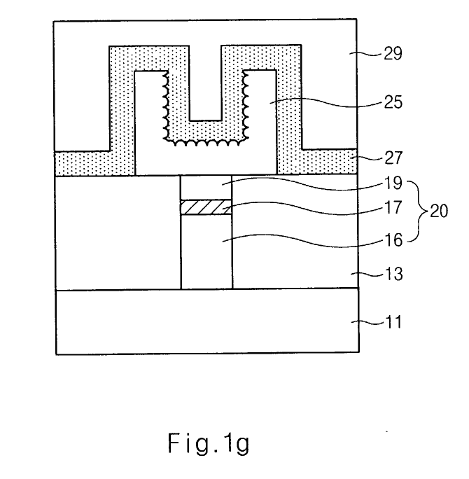

FIGS. 1a to 1g are cross-sectional diagrams illustrating a method for forming a capacitor of a semiconductor device in accordance with a preferred embodiment, wherein the capacitor is a cylinder type capacitor.

Referring to FIG. 1a, a planarized lower insulating layer 13 is formed on a semiconductor substrate 11 which comprises a device isolation film (not shown), a word line (not shown) and a bit line (not shown).

The lower insulating layer 13 is formed of insulating materials having high fluidity such as BPSG.

Thereafter, a storage electrode contact hole 15 exposing a predetermined portion of the substrate 11 is formed in the lower insulating layer 13.

The storage electrode contact hole 15 is formed by etching the lower insulating layer 13 via a photo-etching process using a storage electrode contact mask (not shown) to expose the substrate 11.

Nest, a contact plug 20 is formed to fill the storage electrode contact hole 15.

Preferably, the contact plug 20 has a stacked structure of a polysilicon film 16, a Ti film 17 and a TiN film 19.

Specifically, the stacked structure is formed by first forming a polysilicon film 16 to fill the whole storage electrode contact hole 15 and then planarizing and over-etching to remove a top portion of the polysilicon film in the contact hole 15. Secondly, a Ti Film 17 is formed thereon and then over-etched. Thirdly, a TiN film 19 is formed thereon and then planarized.

The planarization process is performed by utilizing differences in etching selectivity between the polysilicon film 16, the Ti film 17 and the TiN film 19 and the lower insulating layer 13.

Here, the TiN film 19 is a barrier metal layer.

Referring to FIGS. 1b and 1c, a sacrificial insulating layer 21 is formed on the entire surface of the resultant structure.

Then, the sacrificial insulating layer 21 is etched via photo-etching process using a storage electrode mask (not shown) to form the sacrificial insulating layer 21 pattern which exposes top portions of the contact plug 20.

Referring to FIG. 1d, a Ru film 23 having a predetermined thickness and electrically connected to the contact plug 20 is formed on the entire surface of the resultant structure. Here, an iridium film may be used instead of the Ru film 23.

The Ru film 23 preferably has a thickness ranging from 100 to 500 Å and is formed via CVD process. Preferably, the CVD process is performed at a wafer temperature ranging from 250 to 350° C. and under a reaction chamber pressure ranging from 0.1 to 10 torr with O₂ as reaction gas having a flow rate ranging from 10 to 1000 sccm and NH₃ gas having a flow rate ranging from 100 to 2000 sccm using Tris(2,4-octanedionato)ruthenium or Bis(ethylcyclopentadienyl)ruthenium as the Ru source materials. Here, the NH₃ gas removes oxygen contained in the Ru film 23 by deoxidation.

Then, the surface of the Ru film 23 is treated with a RTP under N₂ or NH₃ gas atmosphere. Preferably the RTP is performed at a wafer temperature ranging from 500 to 700° C. for a time period ranging from 30 to 120 seconds with N₂ or NH₃ gas having a flow rate ranging from 100 to 5000 sccm. Here, a rugged surface similar to HSG (Hemi Spherical Grain) is formed on the Ru film.

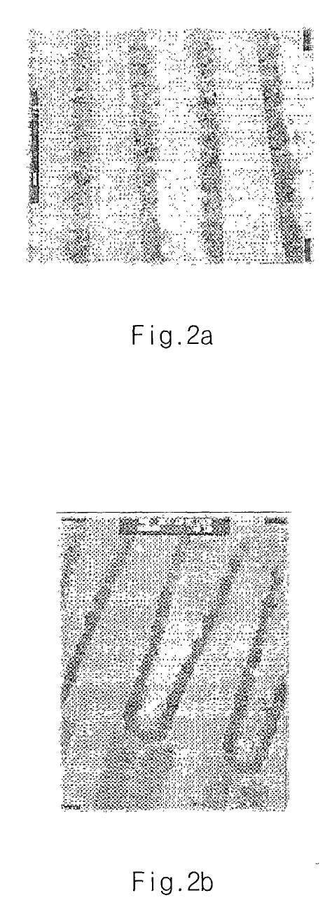

FIGS. 2a to 2b are TEM photographs respectively illustrating the Ru film before and after RTP treatment formed in accordance with a preferred embodiment. Here, it is shown that a rugged surface is formed on the Ru film via RTP treatment.

The formation process of the Ru film may be selectively performed more than once to obtain a Ru film having a desired thickness.

Instead of injecting NH₃ gas to remove oxygen contained in the Ru film 23, NH₃ plasma treatment may be performed on the Ru film after forming the Ru film via CVD method. Here, the process may be selectively performed more than once to obtain a Ru film having a desired thickness. In addition, the process may be performed with injection of the NH₃ gas to maximize the effect.

Preferably, the NH₃ plasma treatment is performed under a reaction chamber pressure ranging from 0.1 to 2.0 torr, with N₃ gas having a flow rate ranging from 30 to 1000 sccm and RF electric power ranging from 30 to 400 Watt for a time period ranging from 5 to 300 seconds.

Referring to FIG. 1e, the Ru film 23 on the top portion of the sacrificial insulating layer 21 pattern is removed to leave the side wall portion and the bottom portion of the storage electrode connected to the contact plug.

Then, the sacrificial insulating layer 21 pattern is removed to form a cylinder type storage electrode 25 connected to the substrate through the contact plug.

Referring to FIG. 1f, a dielectric film 27 is formed on the surface of the storage electrode 25. Here, the dielectric film 27 is selected from the group consisting of Ta₂O₅, BST, PZT, SBT, BLT and combinations thereof.

For example, the process deposition of the dielectric film 27 formed of Ta₂O₅ is performed at a wafer temperature ranging from 300 to 450° C. with Ta(OC₂H₅)₅ as Ru source material in gas state vaporized in a vaporizer having a temperature ranging from 170 to 190° C. and reaction gas O₂ having a flow rate ranging from 10 to 1000 sccm, and under a reaction chamber pressure ranging from 0.1 to 2.0 torr.

Thereafter, the dielectric film 27 is thermally treated. Here, the thermal treatment process is performed at a wafer temperature ranging from 300 to 500° C. under O₂ and N₂ plasma atmosphere, N₂O gas atmosphere, UV/O₃ atmosphere or combinations thereof.

The dielectric film 27 is treated with a RTP at a temperature ranging from 500 to 650° C. under O₂ and N₂ gas atmosphere.

Referring to FIG. 1g, an upper electrode 29 is formed on the surface of the dielectric film 27. Here, the upper electrode 29 is preferably formed of a TiN film or a Ru film.

In another preferred embodiment, a capacitor is formed having a stack structure or a three dimensional structure instead of cylinder type using a separate additional process.

As discussed earlier, the disclosed method for forming a capacitor of a semiconductor device provides improved reliability and characteristics of semiconductor device by removing oxygen from the Ru film using NH₃ gas during the deposition process of the Ru film which is used as storage electrode material or performing an NH₃ plasma treatment after the deposition process of Ru film to inhibit formation of an oxide film at the interface of Ru film and barrier metal layer and then by forming rugged surface on the Ru film with RTP under a N₂ or NH₃ gas atmosphere to obtain a high capacitance for a highly integrated semiconductor device.

What is claimed is:

1. A method for forming a storage electrode of a capacitor of a semiconductor device, the method comprising:
(a) forming a Ru film by performing a CVD process at the presence of NH₃ gas; and
(b) thermally treating the Ru film under N₂ or NH₃ atmosphere to form a rugged surface on the Ru film.

2. The method according to claim 1, wherein the step (a) is performed at the presence of O₂ gas as a reaction gas.

3. The method according to claim 2, wherein the flow ratio of O₂ gas NH₃ gas is 1:2˜20.

4. The method according to any one of claims 1 to 3, wherein the step (a) is performed under the condition that wafer temperature ranges from 250 to 350° C., reaction chamber pressure ranges from 0.1 to 10 torr, Ru source material is Tris(2,4-octanedionato)ruthenium or Bis(ethylcyclopentadienyl)ruthenium, flow rate of O₂ reaction gas ranges from 10 to 1000 sccm and flow rate of NH₃ gas ranges from 100 to 2000 sccm; and the thickness of the Ru film obtained ranges from 100 to 500 Å.

5. The method according to claim 1, wherein the step (b) is performed by RTP (Rapid Thermal Processing).

6. The method according to claim 5, wherein the RTP is performed for 30 to 120 seconds under the condition that wafer temperature ranges from 500 to 700° C., and flow rate of N₂ or NH₃ gas ranges from 100 to 5000 sccm.

7. The method according to any one of claims 1 to 3, further comprising a step of subjecting the Ru film to NH₃ plasma treatment after the step (a).

8. The method according to claim 7, wherein the NH₃ plasma treatment is performed for 5 to 300 seconds under the condition that reaction chamber pressure is ranging from 0.1 to 2.0 torr, NH₃ gas flow rate ranges from 30 to 1000 sccm and RF electric power ranges from 30 to 400 Watt.

9. A method for forming a storage electrode of a capacitor of a semiconductor device, comprising:
(a) forming a Ru film by performing a CVD process;
(b) subjecting the Ru film to a NH₃ plasma treatment; and
(c) thermally treating the Ru film under N₂ or NH₃ atmosphere to form a rugged surface on the Ru film.

10. The method according to claim 9, wherein the step (a) is performed at the presence of O₂ gas as a reaction gas.

11. The method according to any one of claims 9 and 10, wherein the step (a) is performed under the condition that wafer temperature ranges from 250 to 350° C., reaction chamber pressure ranges from 0.1 to 10 torr, Ru source material is Tris(2,4-octanedionato)ruthenium or Bis(ethylcyclopentadienyl)ruthenium, flow rate of O₂ reaction gas ranges from 10 to 1000 sccm and flow rate of NH₃ gas ranges from 100 to 2000 sccm; and the thickness of the Ru film obtained ranges from 100 to 500 Å.

12. The method according to claim 9, wherein the step (b) is performed for 5 to 300 seconds under the condition that reaction chamber pressure is ranging from 0.1 to 2.0 torr, NH₃ gas flow rate ranges from 30 to 1000 sccm and RF electric power ranges from 30 to 400 Watt.

13. The method according to claim 9, wherein the step (b) is performed by RTP (Rapid Thermal Processing).

14. The method according to claim 13, wherein the RTP is performed for 30 to 120 seconds under the condition that wafer temperature ranges from 500 to 700° C., and flow rate of N₂ or NH₃ gas ranges from 100 to 5000 sccm.
